(19) United States
(12) Patent Application Publication
(10) Pub. No.: US 2011/0049707 A1
(43) Pub. Date: Mar. 3, 2011

(54) SEMICONDUCTOR DEVICE AND METHOD OF MANUFACTURING THE SEMICONDUCTOR DEVICE

(75) Inventors: Masaharu Seto, Kanagawa (JP); Soichi Yamashita, Kanagawa (JP); Hirokazu Ezawa, Tokyo (JP)

(73) Assignee: KABUSHIKI KAISHA TOSHIBA, Tokyo (JP)

(21) Appl. No.: 12/850,828

(22) Filed: Aug. 5, 2010

(30) Foreign Application Priority Data
Sep. 2, 2009 (JP) 2009-203107

(51) Int. Cl. H01L 23/485; H01L 21/768

(52) U.S. Cl. 257/737; 438/614; 438/612; 257/E23.021; 257/E21.589; 257/E21.59

(57) ABSTRACT

According to one embodiment, a semiconductor device includes an electrode pad, a protective layer, a bump, and a resin layer. The electrode pad is formed on a semiconductor substrate. The protective layer includes a pad opening formed in the position of the electrode pad. The bump is formed in the pad opening and electrically connected to the electrode pad. The resin layer has a space provided between the resin layer and the bump and is formed on the protective layer via a metal layer. The resin layer is formed by using an adhesive resin material.

### CROSS-REFERENCE TO RELATED APPLICATIONS

This application is based upon and claims the benefit of priority from the prior Japanese Patent Application No. 2009-203107, filed on Sep. 2, 2009; the entire contents of all of which are incorporated herein by reference.

### FIELD

Embodiments described herein relate generally to a semiconductor device and a method of manufacturing the semiconductor device.

### BACKGROUND

According to requests for a reduction in size of electronic apparatuses, an increase in functions, and the like, there is a demand for high-density packaging for semiconductor devices. To improve packaging density for semiconductor devices, for example, a configuration for laminating semiconductor chips is adopted. Concerning the lamination of semiconductor chips, for example, a technology for electrically connecting semiconductor chips via bumps and sealing spaces among the semiconductor chips with a sealing material such as resin is proposed (see, for example, Japanese Patent Application Laid-Open No. H11-261000). In general, the sealing of the semiconductor chips is performed by filling sealing resin in spaces formed by joining the semiconductor chips via the bumps and curing the sealing resin. The sealing resin is injected by making use of the capillary action in the spaces among the semiconductor chips. When the sealing resin is filled after the semiconductor chips are joined, it is more difficult to cause the sealing resin to sufficiently penetrate into the spaces among the semiconductor chips as the spaces are formed smaller according to microminiaturization of the structure of a semiconductor device. When the sealing resin is insufficiently filled, reliability of the semiconductor device falls because the strength of sections joined via the bumps is insufficient.

### BRIEF DESCRIPTION OF THE DRAWINGS

FIGS. 1A to 1I are sectional schematic diagrams for explaining a procedure of a method of manufacturing a semiconductor device according to a first embodiment;

FIGS. 2A and 2B are sectional schematic diagrams for explaining a procedure of a manufacturing method according to a modification of the first embodiment; and

FIGS. 3A to 3K are sectional schematic diagrams for explaining a procedure of a method of manufacturing a semiconductor device according to a second embodiment.

### DETAILED DESCRIPTION

In general, according to one embodiment, a semiconductor device includes an electrode pad, a protective layer, a bump, and a resin layer. The electrode pad is formed on a semiconductor substrate. The protective layer includes a pad opening formed in the position of the electrode pad. The bump is formed in the pad opening and electrically connected to the electrode pad. The resin layer has a space provided between the resin layer and the bump and is formed on the protective layer via a metal layer. The resin layer is formed by using an adhesive resin material.

Exemplary embodiments of a semiconductor device and a method of manufacturing the semiconductor device will be explained below in detail with reference to the accompanying drawings. The present invention is not limited to the following embodiments.

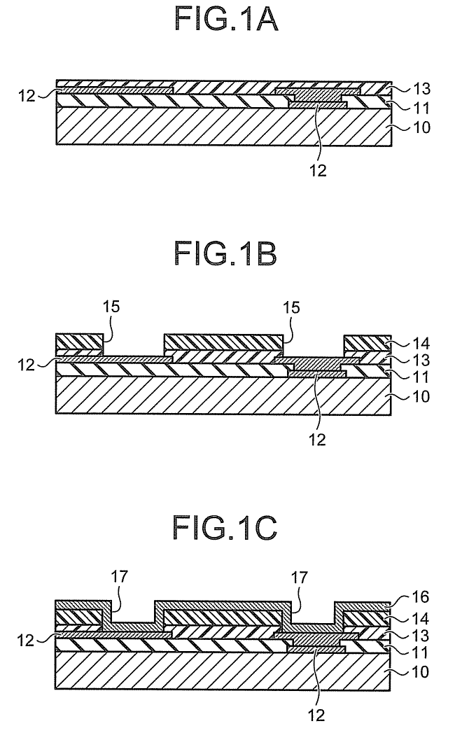

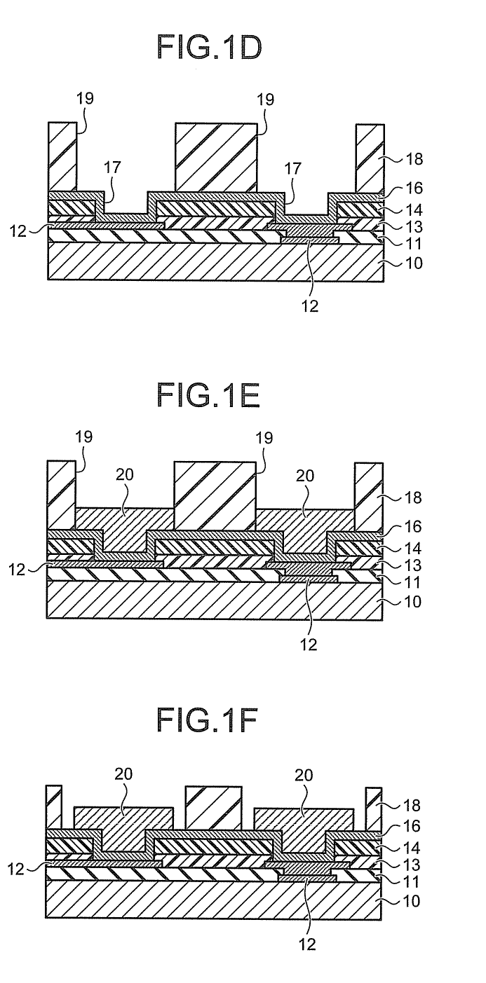

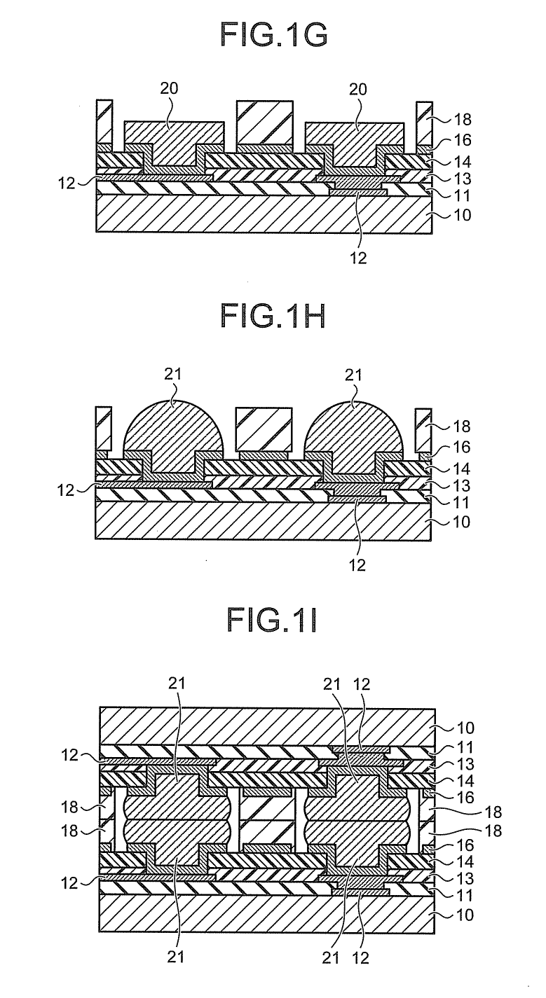

FIGS. 1A to 1I are sectional schematic diagrams for explaining a procedure of a method of manufacturing a semiconductor device according to a first embodiment. At a step shown in FIG. 1A, an interlayer insulation film 11 and electrode pads 12 are formed on an electrode formation surface of a semiconductor substrate 10. The electrode pad 12 formed in an opening of the interlayer insulation film 11 and the electrode pad 12 formed on the interlayer insulation film 11 are shown as an example. A passivation film 13 is formed on the interlayer insulation film 11 and the electrode pads 12.

At a step shown in FIG. 1B, a buffer layer 14 is formed on the passivation film 13. The buffer layer 14 is formed of, for example, a polyimide resin material. Subsequently, pad openings 15 for exposing parts of the electrode pads 12 are formed by patterning the passivation film 13 and the buffer layer 14. The passivation film 13 and the buffer layer 14 form a protective layer. The protective layer only has to include at least one of the passivation film 13 and the buffer layer 14. At a step shown in FIG. 1C, a metal layer 16 that covers the buffer layer 14 and the pad openings 15 is formed. The metal layer 16 is formed of a metal member such as copper (Cu) or lamination of titanium and copper (Ti/Cu). Sections where the metal layer 16 covers the upper surfaces of the electrode pads 12 and the wall surfaces of the pad openings 15 form recesses 17.

At a step shown in FIG. 1D, a resin layer 18 is formed on the metal layer 16. Openings 19 are formed in the resin layer 18 by patterning the formed resin layer 18. The resin layer 18 is patterned by the photolithography technology. The recesses 17 and sections around the recesses 17 in the metal layer 16 are exposed by forming the openings 19 in the resin layer 18. The resin layer 18 is formed by using an adhesive resin material. As the adhesive resin material, for example, a thermoplastic resin material that shows adhesion through heating is used.

The resin layer 18 can also be formed of a resin material having photosensitivity as well as adhesiveness. When the resin layer 18 is formed of the resin material having photosensitivity, the resin layer 18 is patterned by exposure and development of the resin layer 18 itself. Besides, it is also possible to form a resist on the resin layer 18 and pattern the resin layer 18 by performing etching with the resist as a mask.

At a step shown in 1E, bump material layers 20 are formed on the metal layer 16 by electrolytic plating with the resin layer 18 as a mask. As a material of the bump material layers 20, a solder material such as tin (Sn) or an alloy of copper and tin (Cu/Sn) is used. At a step shown in FIG. 1F, the resin layer 18 is retracted by desired thickness. The retraction of the resin layer 18 is carried out by immersion in an alkali solution and ashing. The retraction of the resin layer 18 can also be carried out by only one of the immersion in the alkali solution and the ashing. When a chemical is caused to penetrate into a surface of the resin layer 18 on the bump material layers 20 side, the immersion in the alkali solution is particularly useful in facilitating retraction of sides of the resin layer 18. When the adhesiveness of the resin layer 18 falls because the surface of the resin layer 18 is denatured by the chemical, the ashing is useful for removing the denatured surface and secure sufficient adhesiveness. Spaces are provided between the resin layer 18 and the bump material layers 20 by the retraction of the resin layer 18 at this step. The metal layer 16 is exposed in the spaces formed between the resin layer 18 and the bump material layers 20.

At a step shown in FIG. 1G, the metal layer 16 in sections exposed in the spaces between the resin layer 18 and the bump material layers 20 is removed by etching. After the removal of the metal layer 16 at the step shown in FIG. 1G, at a step shown in FIG. 1H, bumps 21 having a convex shape are formed by carrying out reflow of the bump material layers 20 and the solder material joined to the metal layer 16. In a structure formed at the steps up to the step shown in FIG. 1H, the resin layer 18 is formed on the buffer layer 14 via the metal layer 16. The bumps 21 are electrically connected to the electrode pads 12 via the metal layer 16. The metal layer 16 under the resin layer 18 and the metal layer 16 under the bumps 21 are insulated from each other because spaces are provided in the metal layer 16.

At a step shown in FIG. 1I, structures formed at the steps up to the step shown in FIG. 1H are joined. The bumps 21 of both the structures are soldered and the resin layers 18 are set in contact with each other. Both the structures are joined to each other by the soldering of the bumps 21 and bonding and curing of the resin layers 18 having adhesiveness. The thickness of the resin layer 18 left at the step shown in FIG. 1F is set such that the resin layers 18 can be sufficiently compression-bonded at the step shown in FIG. 1I. Through the steps explained above, a semiconductor device having structure shown in FIG. 1I is manufactured.

As a material of the resin layer 18, for example, polyimide resin having adhesiveness and photosensitivity is used. Besides, as the material of the resin layer 18, for example, epoxy resin, phenolic resin, or benzocyclobutene can also be used. The material of the resin layer 18 only has to have at least adhesiveness and is not limited to the material used in this embodiment.

The resin layer 18 used as the mask in the formation of the bump material layers 20 is left without being removed after being retracted at the step shown in FIG. 1F. In the semiconductor device manufactured in this embodiment, the resin layers 18 form spacers in sections joined via the bumps 21. Because the resin layers 18 are used as the spacers, a step for filling sealing resin after joining semiconductor chips is unnecessary. Therefore, sufficient strength of the sections joined via the bumps 21 can be secured by bonding the resin layers 18. Consequently, there is an effect that it is possible to secure sufficient strength of a laminated structure formed via the bumps 21 and obtain a semiconductor device having high reliability. When it is difficult to fill the sealing resin because, for example, a space between the semiconductor chips is narrow, it is possible to easily obtain sufficient strength by applying this embodiment. In this embodiment, the metal layer 16 after the removal of the sections exposed in the spaces at the step shown in FIG. 1G is left together with the resin layer 18. The metal layer 16 left under the resin layer 18 can also be caused to function as, for example, a heat dissipating member that dissipates heat from the semiconductor device.

The manufacturing method according to this embodiment is not limited to the method of joining the structures formed at the steps up to the step shown in FIG. 1H. At least one of the structures to be joined only has to be formed through the steps up to the step shown in FIG. 1H. The structure to be joined with the structure formed at the steps up to the step shown in FIG. 1H only has to be a structure having at least pads or the like joined with the bumps 21. The structure can be a semiconductor chip or a mounting board having any configuration. The structures are not always joined by joining the resin layers 18 provided in the respective structures and can also be joined by using the resin layer 18 provided in one structure. The thickness of the resin layer 18 can be set as appropriate according to the configuration of a semiconductor device.

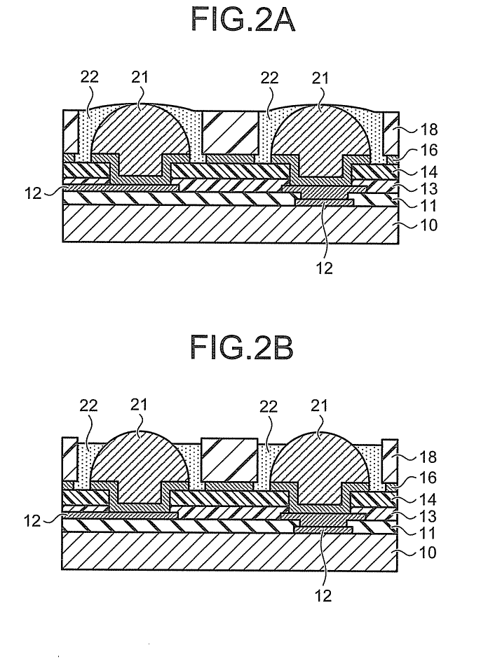

FIGS. 2A and 2B are sectional schematic diagrams for explaining a procedure of a manufacturing method according to a modification of this embodiment. At a step shown in FIG. 2A, an insulative member 22 is applied to the surface of the structure formed at the steps up to the step shown in FIG. 1H. The insulative member 22 is filled between laminated sections of the bumps 21 and the metal layer 16 and laminated sections of the resin layer 18 and the metal layer 16. As the insulative member 22, for example, a resin material that has low viscosity and can easily flow is used. After the filled insulative member 22 is cured, at a step shown in FIG. 2B, the insulative member 22 on the surfaces of the bumps 21 is removed by ashing.

Intrusion of dust or the like into spaces between the laminated sections of the bumps 21 and the metal layer 16 and the laminated sections of the resin layer 18 and the metal layer 16 is prevented by filling the insulative member 22 in the spaces. This makes it possible to prevent short-circuit between the metal layer 16 under the resin layer 18 and the bumps 21 and metal layer 16 under the bumps 21. Intrusion of the insulative member 22 into a space between the bumps 21 is prevented by removing the insulative member 22 applied to the surfaces of the bumps 21. This makes it possible to secure electric connection between the bumps 21. The insulative member 22 can also be a member obtained by melting the resin layer 18 when the reflow is carried out.

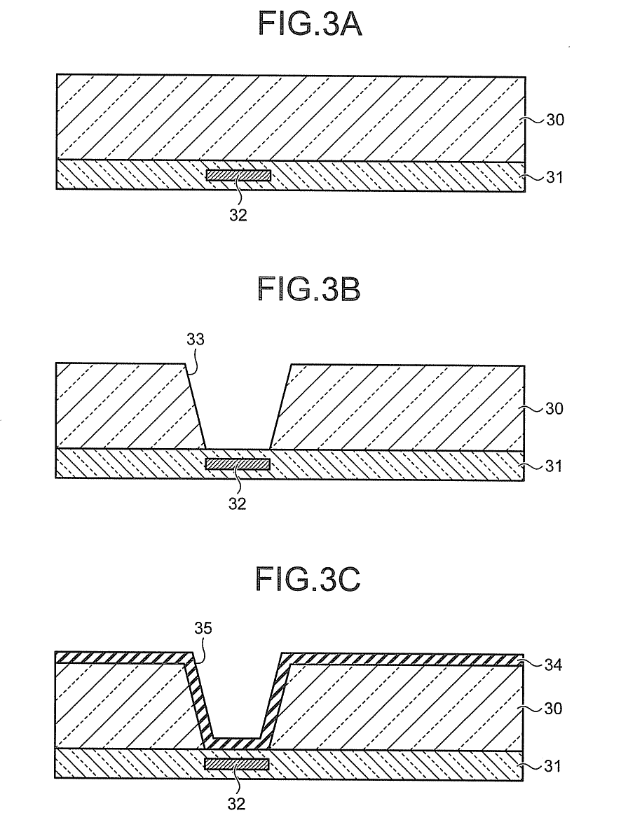

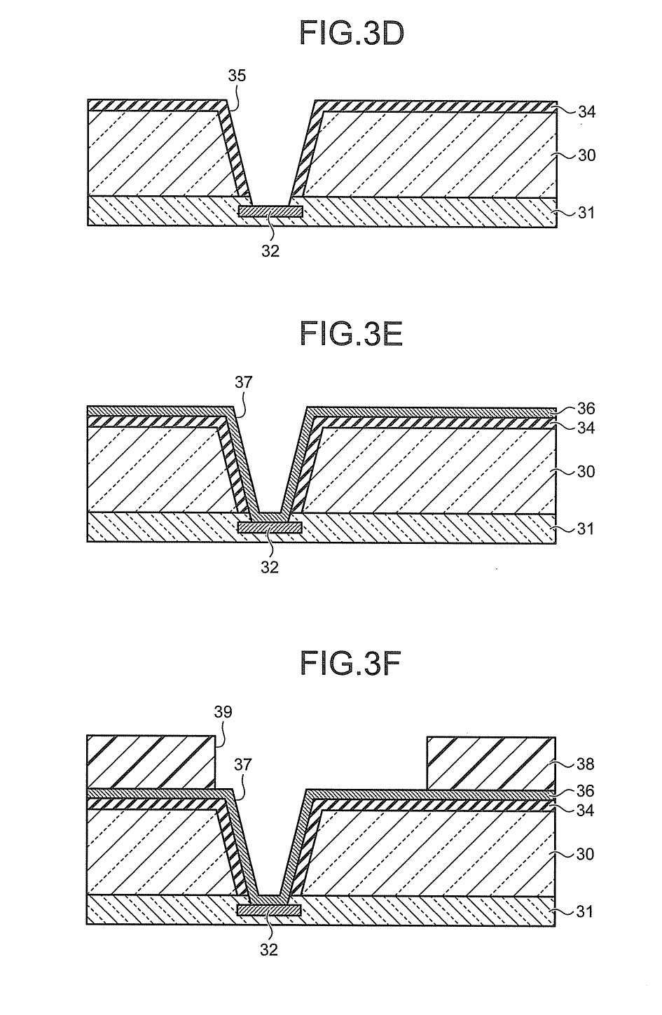

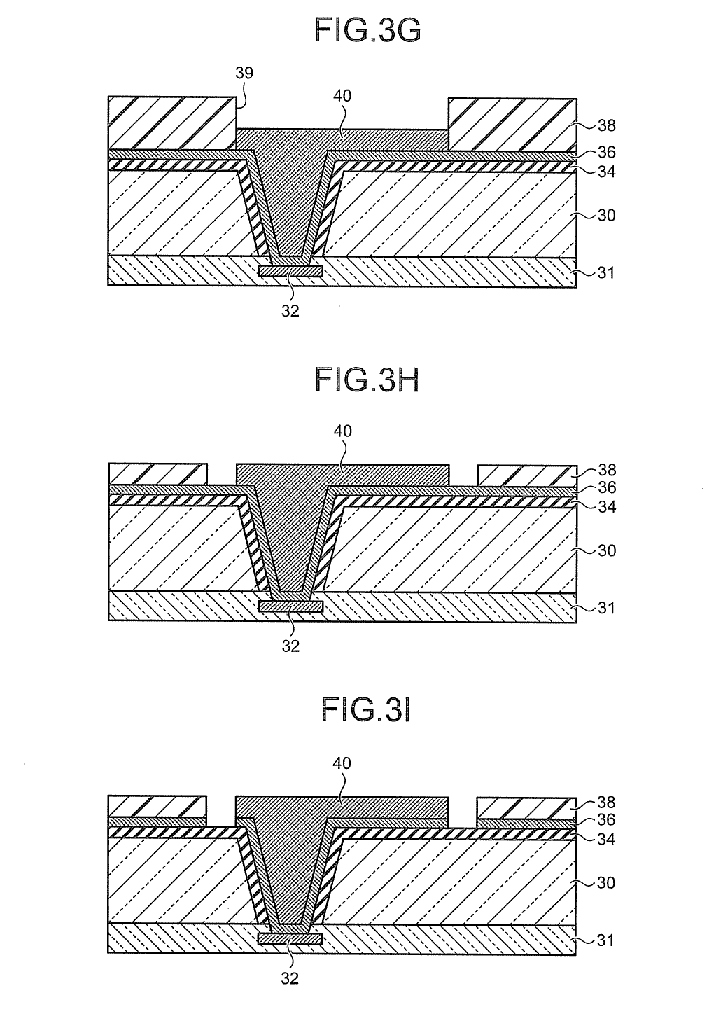

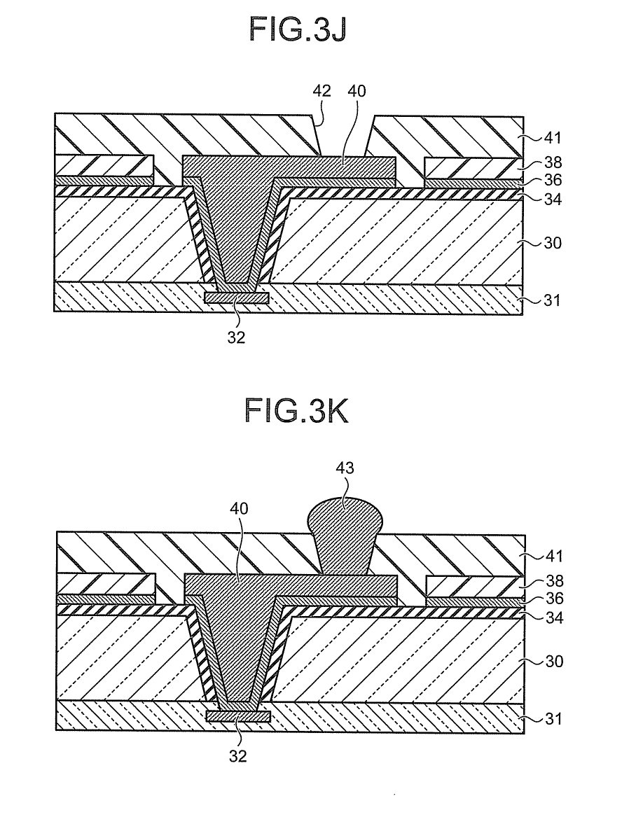

FIGS. 3A to 3K are sectional schematic diagrams for explaining a procedure of a method of manufacturing a semiconductor device according to a second embodiment. A semiconductor device manufactured in this embodiment includes, for example, a solid-state imaging device (not shown). At a step shown in FIG. 3A, a filter layer 31 and an electrode pad 32 are formed on a first surface side of a semiconductor substrate 30. The solid-state imaging device is provided on the first surface side of the semiconductor substrate 30. The filter layer 31 includes, for example, a color filer corresponding to RGB pixels and a passivation film. The electrode pad 32 is provided in the filter layer 31. The electrode pad 32 is electrically connected to the solid-state imaging device.

At a step shown in FIG. 3B, a through via 33 is formed in a position on the electrode pad 32 in the semiconductor substrate 30. The through via 33 is formed by applying etching to the semiconductor substrate 30 with a resist as a mask from a second surface on the opposite side of the first surface in the semiconductor substrate 30. A section on the electrode pad 32 in the filter layer 31 is exposed by forming the through via 33 in the semiconductor substrate 30.

At a step shown in FIG. 3C, an insulation layer 34 that covers the second surface side of the semiconductor substrate 30 and the through via 33 is formed. A section where the insulation layer 34 covers the exposed section of the filter layer 31 and the wall surface of the through via 33 forms a recess 35. At a step shown in FIG. 3D, the insulation layer 34 in the bottom section of the recess 35 is removed and the filter layer 31 under the insulation layer 34 is removed to form a pad opening in the filter layer 31. Consequently, the electrode pad 32 is exposed at the bottom of the recess 35. At a step shown in FIG. 3E, a metal layer 36 that covers the insulation layer 34 and the pad opening is formed. The metal layer 36 is formed of a metal member such as Cu or Ti/Cu. The electrode pad 32 and the metal layer 36 are connected to each other via the pad opening formed in the filter layer 31. A section where the metal layer 36 covers the upper surface of the electrode pad 32 and the wall surface of the recess 35 forms a recess 37.

At a step shown in FIG. 3F, a resin layer 38 formed of a resin material is formed on the metal layer 36. An opening 39 is formed in the resin layer 38 by patterning the formed resin layer 38. The resin layer 38 is patterned by the photolithography technology. A part of the metal layer 36 including the recess 37 is exposed by forming the opening 39 in the resin layer 38.

At a step shown in FIG. 3G, a plated layer 40 is formed on the metal layer 36 by the electrolytic plating with the resin layer 38 as a mask. The plated layer 40 forms rewiring. At a step shown in FIG. 3H, the resin layer 38 is retracted by desired thickness. As in the first embodiment, the retraction of the resin layer 38 is carried out by, for example, at least one of immersion in an alkali solution and ashing. A space in which the metal layer 36 is exposed is formed between the resin layer 38 and the plated layer 40 by the retraction of the resin layer 38 at this step.

At a step shown in FIG. 3I, the metal layer 36 in a section exposed in the space between the resin layer 38 and the plated layer 40 is removed by etching. At a step shown in FIG. 3J, a resin layer 41 is further formed over the entire side of a structure formed at the steps up to the step shown in FIG. 3I on which the plated layer 40 and the resin layer 38 are formed. The resin layer 41 is penetrated into the section where the metal layer 36 is removed in FIG. 3I. This makes it possible to prevent short-circuit between a laminated section of the plated layer 40 and the metal layer 36 and the metal layer 36 under the resin layer 38. The resin layer 38 used as the mask in the electrolytic plating and the resin layer 41 formed at this step are integrated and used for protection and insulation of wires and the like formed on the second surface side of the semiconductor substrate 30. The resin layer 41 at this step can also be formed after the resin layer 38 used as the mask in the electrolytic plating is removed in advance.

Subsequently, an opening 42 for exposing a part of the plated layer 40 is formed by patterning the resin layer 41. At a step shown in FIG. 3K, a solder ball 43 is mounted on a section exposed by the opening 42 in the plated layer 40. Through the steps explained above, a semiconductor device having structure shown in FIG. 3K is manufactured. The metal layer 36, the plated layer 40, and the solder ball 43 function as a through electrode that draws out electric connection with the electrode pad 32 to the second surface side of the semiconductor substrate 30. The solder ball 43 functions as an external connection terminal.

In this embodiment, the metal layer 36 after the removal of the section exposed in the space at the step shown in FIG. 3I is left under the resin layer 38. The left metal layer 36 can be caused to function as a light blocking member for blocking light. Therefore, even if the light blocking member is not separately provided, it is possible to block light in a desired region of the semiconductor device. Because light is blocked by the metal layer 36, it is possible to prevent light from being made incident on the solid-state imaging device from the second surface of the semiconductor substrate 30 and prevent occurrence of ghost, reflection of a wiring pattern, and the like. The left metal layer 36 can also be caused to function as a heat dissipating member that dissipates heat from the semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the sprit of the inventions. The accompanying claims and their equivalents are intended to cover such forms or modifications as would fall within the scope and spirit of the inventions.

What is claimed is:

1. A semiconductor device comprising:
an electrode pad formed on a semiconductor substrate;
a protective layer including a pad opening formed in a position of the electrode pad;
a bump formed in the pad opening and electrically connected to the electrode pad; and
a resin layer that has a space provided between the resin layer and the bump and is formed on the protective layer via a metal layer, wherein
the resin layer is formed by using an adhesive resin material.

2. The semiconductor device according to claim 1, wherein the resin layer forms a spacer in a section joined via the bump.

3. The semiconductor device according to claim 1, wherein the protective layer includes at least one of a passivation film and a buffer layer.

4. The semiconductor device according to claim 1, further comprising an insulative member filled between the bump and the metal layer.

5. A method of manufacturing a semiconductor device, comprising:
forming an electrode pad on a semiconductor substrate;
forming a protective layer including a pad opening formed in a position of the electrode pad,;
forming a metal layer that covers the protective layer and the pad opening;
forming a resin layer on the metal layer;
patterning the resin layer;
forming a bump material layer on the metal layer by performing electrolytic plating with the resin layer as a mask;
retracting the resin layer by desired thickness to thereby form a space for exposing the metal layer between the resin layer and the bump material layer; and
carrying out reflow of the bump material layer after removing the metal layer in a section exposed in the space, wherein
the resin layer is formed by using an adhesive resin material.

6. The method of manufacturing a semiconductor device according to claim 5, further comprising leaving the resin layer after being retracted by the desired thickness and the metal layer from which the section exposed in the space is removed.

7. The method of manufacturing a semiconductor device according to claim 5, further comprising joining structures via the resin layer.

8. The method of manufacturing a semiconductor device according to claim 7, further comprising bringing the resin layers formed in the structures into contact with each other.

9. The method of manufacturing a semiconductor device according to claim 5, further comprising joining structures by performing soldering of bumps formed by carrying out the reflow.

10. The method of manufacturing a semiconductor device according to claim 9, further comprising carrying out soldering of the bumps formed in the structures.

11. The method of manufacturing a semiconductor device according to claim 5, wherein the adhesive resin material has photosensitivity.

12. The method of manufacturing a semiconductor device according to claim 5, wherein the bump material layer is formed on a section of the metal layer that covers the electrode pad and a section around the section.

13. The method of manufacturing a semiconductor device according to claim 5, wherein the retraction of the resin layer is carried out by at least one of immersion in an alkali solution and ashing.

14. The method of manufacturing a semiconductor device according to claim 5, further comprising filling an insulative member between a laminated section of a bump formed by carrying out the reflow and the metal layer and a laminated section of the resin layer and the metal layer.

15. The method of manufacturing a semiconductor device according to claim 14, further comprising removing the insulative member applied to a surface of the bump.

16. A method of manufacturing a semiconductor device, comprising:
forming, on a semiconductor substrate including an electrode pad, a metal layer connected to the electrode pad via a pad opening;
forming a resin layer on the metal layer;
patterning the resin layer;
forming plated layer on the metal layer by performing electrolytic plating with the resin layer as a mask;
retracting the resin layer by desired thickness to thereby form a space for exposing the metal layer between the resin layer and the plated layer; and
removing the metal layer in a section exposed in the space.

17. The method of manufacturing a semiconductor device according to claim 16, further comprising leaving the metal layer from which the section exposed in the space is removed.

18. The method of manufacturing a semiconductor device according to claim 16, further comprising:
forming a through via that pierces through the semiconductor substrate from a first surface on a side on which the electrode pad is provided in the semiconductor substrate to a second surface on an opposite side of the first surface;
forming an insulation layer that covers the second surface and the through via;
removing a section in which the pad opening is formed in the insulation layer; and
forming the metal layer that covers the pad opening and the insulation layer.

19. The method of manufacturing a semiconductor device according to claim 16, further comprising:
forming a filter layer on the semiconductor substrate;
forming the electrode pad in the filter layer; and
removing a section on the electrode pad in the filter layer to thereby form the pad opening.

20. The method of manufacturing a semiconductor device according to claim 16, further comprising forming a resin layer that covers the space in which the metal layer is removed.
